(19) United States
(12) Patent Application Publication
(10) Pub. No.: US 2026/0120751 A1
(43) Pub. Date: Apr. 30, 2026

(54) APPARATUSES AND METHODS FOR IMPEDANCE CALIBRATION IN MEMORY DEVICES

(71) Applicant: MICRON TECHNOLOGY, INC., BOISE, ID (US)

(72) Inventors: Tetsuya Arai, Sagamihara (JP); Toru Ishikawa, Sagamihara (JP)

(73) Assignee: MICRON TECHNOLOGY, INC., Boise, ID (US)

(21) Appl. No.: 19/352,226

(22) Filed: Oct. 7, 2025

Related U.S. Application Data
(60) Provisional application No. 63/711,617, filed on Oct. 24, 2024.

(51) Int. Cl. G11C 11/4093; H03K 19/00

(52) U.S. Cl. CPC G11C 11/4093; H03K 19/0005

(57) ABSTRACT

An example method includes for a first calibration impedance, determining a first pulldown calibration code to set a replica pulldown driver circuit to a first impedance. A first pullup calibration code is determined for a replica pullup driver circuit based on the first impedance. The first pulldown and pullup calibration codes are stored. For a second calibration impedance, a second pulldown calibration code is determined to set the replica pulldown driver circuit to a second impedance. A second pullup calibration code is determined for the replica pullup driver circuit based on the second impedance. The second pulldown and pullup calibration codes are stored. The first and second calibration impedances may be on-die calibration impedances. The first and second calibration impedances may be external calibration impedances. The first and second calibration impedances may be provided by a calibration impedance having an adjustable impedance.

### CROSS-REFERENCE TO RELATED APPLICATIONS

This application claims the filing benefit of U.S. Provisional Application No. 63/711,617, filed Oct. 24, 2024. This application is incorporated by reference herein in its entirety and for all purposes.

### BACKGROUND

A semiconductor device, such as a DRAM (Dynamic Random Access Memory) includes an output unit for outputting data to the outside. The output unit is designed so as to provide a desired impedance when activated. However, due to influences such as process deviations and temperature changes, the desired impedance as designed is not necessarily obtained. For this reason, in the semiconductor device in which the impedance of the output unit needs to be controlled with high precision, an impedance adjusting circuit, which is referred to as a calibration circuit, performs an impedance calibration operation to precisely set driver impedance.

### BRIEF DESCRIPTION OF DRAWINGS

FIG. 1 is a block diagram showing a configuration of a semiconductor system provided with a semiconductor device according to an embodiment of the disclosure.

FIG. 2 is a block diagram of a semiconductor device according to an embodiment of the disclosure.

FIG. 3 is a diagram of a predriver circuit and data output buffer circuit according to an embodiment of the disclosure.

FIG. 4 is a diagram of the predriver circuit and data output buffer circuit according to an embodiment of the disclosure.

FIG. 5 is a diagram of the predriver circuit and data output buffer circuit according to an embodiment of the disclosure.

FIG. 6 is a circuit diagram of a pullup data driver circuit, pullup driver logic, and data predriver circuit according to an embodiment of the disclosure.

FIG. 7 is a circuit diagram of a pulldown data driver circuit, pulldown driver logic, and data predriver circuit according to an embodiment of the disclosure.

FIG. 8 is a diagram of a calibration circuit according to an embodiment of the disclosure.

FIG. 9 is a diagram of a calibration circuit according to an embodiment of the disclosure.

FIG. 10 is a timing diagram for determining pulldown and pullup calibration codes according to an embodiment of the disclosure.

FIG. 11 is a diagram of a calibration circuit according to an embodiment of the disclosure.

FIG. 12 is a diagram of a calibration circuit according to an embodiment of the disclosure.

### DETAILED DESCRIPTION

The present disclosure provides descriptions of non-limiting example embodiments and is in no way intended to limit the scope of the disclosure or its applications or uses. In the following detailed description of embodiments of the present technology, reference is made to the accompanying drawings, which form a part hereof and in which are shown by way of illustration specific embodiments in which the described systems and methods may be practiced. These embodiments are described in sufficient detail to enable those skilled in the art to practice presently disclosed systems and methods, and it is to be understood that other embodiments may be utilized, and that structural and logical changes may be made without departing from the spirit and scope of the disclosure. Moreover, for the purpose of clarity, detailed descriptions of certain features will not be discussed when they would be apparent to those with skill in the art, so as not to obscure the description of embodiments of the disclosure. The following detailed description is therefore not to be taken as limiting, and the scope of the disclosure is defined only by the appended claims.

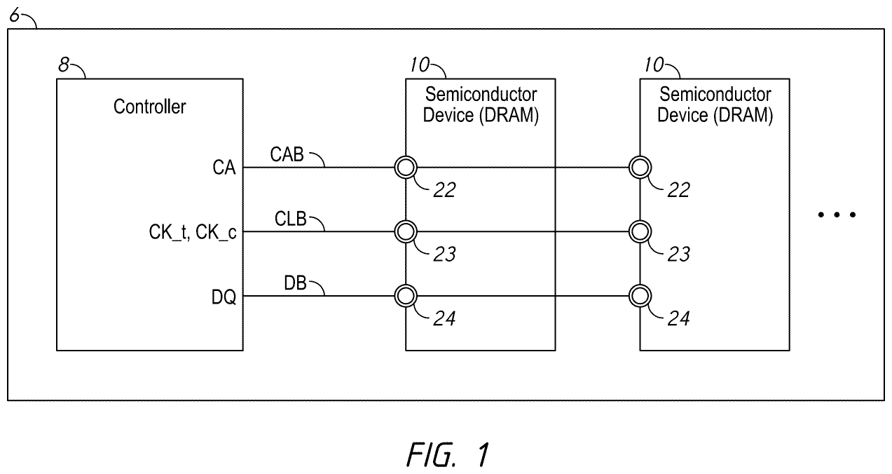

FIG. 1 is a block diagram showing a configuration of a semiconductor system 6 provided with a semiconductor device 10 according to an embodiment of the disclosure.

The semiconductor system 6 includes a plurality of semiconductor devices 10 and a controller 8 that controls these devices. Although not particularly limited, each semiconductor device 10 can be a DRAM integrated into a single semiconductor chip, which carries out reading and writing operations based upon command-address signals CA and external clock signals CK_t and CK_c, supplied from the controller 8. Example DRAMs include a Double Data Rate (DDR) type, a lower power Double Data Rate (LPDDR) type, low power wide input/output type, stacked DRAM devices, as well as other types of DRAMs and DRAM systems. The semiconductor devices 10 may be included in a memory module in some embodiments of the disclosure. In some embodiments of the disclosure, the semiconductor system 5 may be a system on chip (SOC), system on wafer (SOW), or other type of semiconductor system.

The command information and address information included in the command-address signals CA are commonly supplied to command-address terminals 22 the plural semiconductor devices 10 through a command-address bus CAB. Although not shown in FIG. 1, the controller 8 may provide chip select signals CS_n to each of the semiconductor devices 10 on respective chip select lines. The external clock signals CK_t and CK_c are commonly supplied to clock terminals 23 of the plural semiconductor devices 10 through a clock bus CLB.

Read data DQ is outputted from the data input/output terminal 24 of each semiconductor device 10 at the time of a reading operation, and is then supplied to the controller 8 through the data bus DB. On the other hand, write data DQ outputted from the controller 8 at the time of a writing operation is supplied to the data input/output terminal 24 of each semiconductor device 10 through the data bus DB. The data bus DB is commonly coupled to the plural semiconductor devices 10 as shown in FIG. 1.

Each semiconductor device 10 includes data input/output circuits coupled to the data input/output terminals 24. Data driver circuits included in a data output buffer circuit of the data input/output circuit include adjustable impedances that are adjustable and may be set to provide an impedance to the input/output terminals 24. The adjustable impedances are calibrated using calibration impedances RZQ. In some embodiments of the disclosure, one or more calibration impedances are included in each semiconductor device 10. Calibration impedances that are included in each semiconductor device 10 may be referred to as “on-die” calibration impedances. On-die calibration impedances may be formed in semiconductor structures that are included in the semiconductor device 10. In some embodiments of the disclosure, a calibration terminal that is configured to be coupled to a circuit that external to the semiconductor device 10 is provided in each semiconductor device 10. The calibration terminal may be coupled to a calibration impedance that is external to the semiconductor devices 10. In some embodiments, each of a plurality of external calibration impedances is coupled to a respective calibration terminal.

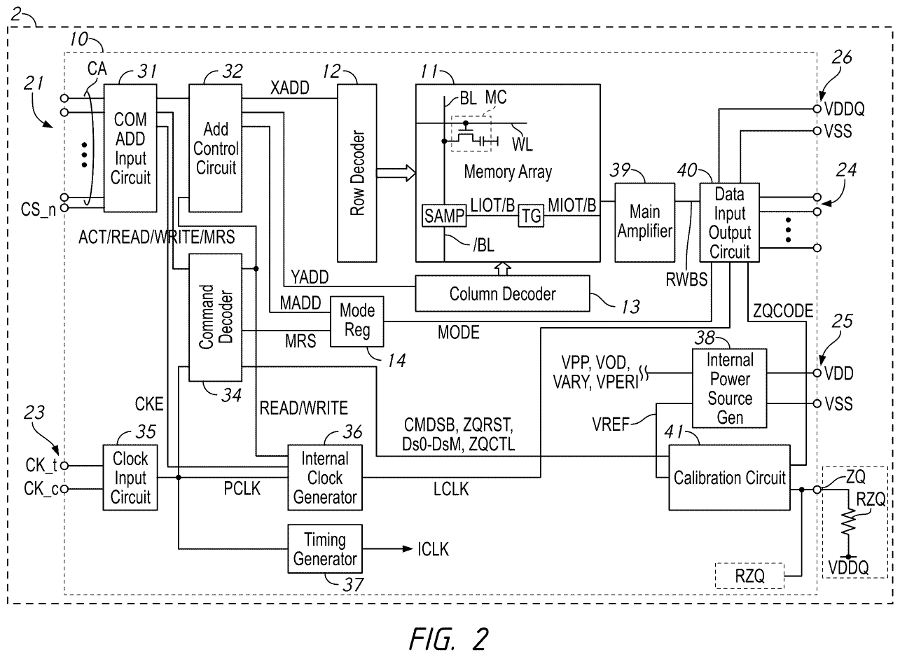

FIG. 2 is a block diagram of a semiconductor device 10 according to an embodiment of the disclosure.

The semiconductor device 10 is assembled on an external substrate 2. The external substrate 2 may be a memory module substrate, a mother board, a semiconductor wafer forming the semiconductor system 6. In some embodiments of the disclosure, the calibration impedance RZQ is an external circuit provided on the external substrate 2 and is coupled to a terminal ZQ that is configured to be coupled to an external circuit. In some embodiments of the disclosure, the calibration impedance RZQ is alternatively or additionally included in the semiconductor device 10. Calibration impedances that are included in each semiconductor device 10 may be referred to as “on-die” calibration impedances. On-die calibration impedances may be formed in semiconductor structures that are included in the semiconductor device 10. The calibration impedance RZQ is used as a reference impedance by the calibration circuit 41.

As shown in FIG. 2, the semiconductor device 10 has a memory cell array 11. The memory cell array 11 includes a plurality of word lines WL and a plurality of bit lines BL, /BL, and has a configuration in which memory cells MC are disposed on these intersections. The selection of the word line WL is carried out by a row decoder 12, and the selection of the bit lines BL, /BL is carried out by a column decoder 13.

The paired bit lines BL, /BL are coupled to a sense amplifier SAMP in the memory cell array 11. The sense amplifier SAMP amplifies an electric potential difference occurring between the bit lines BL and /L and supplies read data thus obtained to a complementary local IO line LIOT/LIOB. The read data supplied to the local IO line LIOT/LIOB is transferred to a complementary main IO line MIOT/MIOB through a switch circuit TG. Then, the read data on the main IO line MIOT/MIOB is converted to a signal of a single end format by a main amplifier 39, and supplied to a data input/output circuit 40 through a read/write bus RWBS. The data input/output circuit 40 includes data output buffer circuits that provide read data to the data input/output terminal 24 and further includes data input buffer circuits that receive write data from the data input/output terminal 24.

The semiconductor device 10 includes command-address terminals 21, a clock terminal 23, a data input/output terminal 24, power supply terminals 25, 26, and a calibration terminal ZQ, as external terminals.

The command-address (CA) terminals 21 are terminals to which command-address signals CA are externally inputted. Address information included in the command-address signals CA is supplied to an address control circuit 32 through a command-address input circuit 31. Of the address information supplied to the address control circuit 32, a row address XADD is supplied to the row decoder 12, a column address YADD is supplied to the column decoder 13, and a mode signal MADD is supplied to a mode register 14.

The mode register 14 is a circuit for use in setting a parameter indicating an operation mode of the semiconductor device 10. A mode signal outputted from the mode register 14 includes an impedance selection signal MODE. The impedance selection signal MODE is supplied to the data input/output circuit 40. The impedance selection signal MODE is a signal for use in selecting an output impedance at the time of a reading operation. In some embodiments, the MODE signal alternatively or additionally is a signal for use in selecting a drive strength of data driver circuits included in data output buffer circuits of the data input/output circuit 40.

The command-address (CA) terminals 21 are terminals to which command-address signals are externally inputted. Command information included in the CA signals is supplied to a command decode circuit 34 through a command-address input circuit 31. Moreover, a select signal CS_n is also supplied to the command-address input circuit 31. The command decode circuit 34 generates various internal commands by decoding the command information. The internal commands include an active signal ACT, a read signal READ, a write signal WRITE, a mode register setting signal MRS, a calibration signal CMDSB, a reset signal ZQRST, drive strength signals Ds0-DsM, calibration control signals ZQCTL, and the like.

The active signal ACT can be activated when the CA signals indicate a row access (active command). When the active signal ACT is activated, the row address XADD latched by the address control circuit 32 is supplied to the row decoder 12. Thus, a word line WL specified by the row address XADD is selected.

The read signal READ and the write signal WRITE can be respectively activated when the CA signals indicate the read command and write command. When the read signal READ or the write signal WRITE is activated, a column address YADD latched by the address control circuit 32 is supplied to the column decoder 13. Thus, a bit line BL or /L specified by the corresponding column address YADD is selected.

Therefore, by inputting the active command and the read command, as well as inputting a row address XADD and a column address YADD in synchronism with these, read data is read out from a memory cell MC specified by these row address XADD and column address YADD. The read data DQ is externally outputted from the data input/output terminal 24 through the main amplifier 39 and the data input/output circuit 40.

On the other hand, by inputting the active command and the write command, as well as inputting a row address XADD and a column address YADD in synchronism with these, with write data DQ being then inputted to the data input/output terminal 24, the write data DQ is supplied to the memory cell array 11 through the data input/output circuit 40 and the main amplifier 39, and written onto a memory cell MC specified by the row address XADD and the column address YADD.

The mode register setting signal MRS is activated when the command signal COM indicates a mode register setting command. Therefore, by inputting the mode register setting command, as well as inputting a mode signal MADD from the command-address terminals 21 in synchronism with these, the set value of the mode register 14 can be rewritten.

The calibration signal CMDSB can be activated when the CA signals indicate a calibration command. When the calibration signal CMDSB is activated, the calibration circuit 41 carries out a calibration operation so as to generate an impedance code ZQCODE.

Upon application of power to the semiconductor circuit 10, the command decode circuit 34 executes an initial setting operation so that the reset signal ZQRST and the calibration signal CMDSB are activated in this order. The reset signal ZQRST is a signal for resetting the calibration circuit 41. Thus, upon application of power to the semiconductor device 10, after having been reset to the initial state, the calibration circuit 41 automatically executes a calibration operation. In the case when a reset command is issued from the outside also, the command decode circuit 34 activates the reset signal ZQRST and the calibration signal CMDSB in this order. Drive strength settings for data drivers included in data output buffer circuits of the data input/output circuit 40 may be set by drive strength signals Ds0-DsM provided by the command decode circuit 34. The drive strength setting may be set in the mode register 14 and received by the command decode circuit 34. Calibration control signals ZQCTL are provided to circuits included in the calibration circuit 41 during a calibration operation.

Here, going back to the explanation of the external terminal provided in the semiconductor device 10, the external clock signals CK_t and CK_c are inputted to the clock terminal 23. The external clock signal CK_t and the external clock signal CK_c are mutually complementary signals, and are supplied to the clock input circuit 35. Upon receipt of the external clock signals CK_t and CK_c, the clock input circuit 35 generates an internal clock signal PCLK. The internal clock signal PCLK is supplied to the internal clock generation circuit 36 that is activated by the clock enable signal CKE. An internal clock signal LCLK, which is thus phase-controlled, is generated. Although not particularly limited, a DLL circuit may be used as the internal clock generation circuit 36. The internal clock signal LCLK is supplied to the data input/output circuit 40, and used as a timing signal that determines the output timing of the read data DQ.

The internal clock signal PCLK is also supplied to a timing generator 37, which generates various internal clock signals ICLK. The various internal clock signals ICLK are supplied to circuit blocks, such as the address control circuit 32 and command decode circuit 34, so as to regulate the operation timings of these circuit blocks.

The power supply terminal 25 is a terminal through which power supply electric potentials VDD and VSS are supplied. The power supply electric potentials VDD and VSS are first supplied to an internal power supply generation circuit 38. Based upon the power supply electric potentials VDD and VSS, the internal power supply generation circuit 38 generates various internal electric potentials VPP, VOD, VARY, VPERI and VCCP as well as reference electric potential VREF. The internal electric potential VPP has an electric potential to be mainly used by the row decoder 12, the internal electric potentials VOD and VARY have electric potentials to be used by the sense amplifier SAMP in the memory cell array 11. The internal electric potential VPERI has an electric potential to be used by many other circuit blocks. The internal electric potential VCCP is a pumped voltage used by various circuits included in the semiconductor device 10. The reference electric potential VREF is a reference electric potential to be used in the calibration circuit 41.

The power supply terminal 26 is a terminal through which power supply electric potentials VDDQ and VSS are supplied. The power supply electric potentials VDDQ and VSS are first supplied to the data input/output circuit 40. The power supply electric potentials VDDQ and VSS respectively have the same electric potentials as those of the power supply electric potentials VDD and VSS to be supplied to the power supply terminal 25. However, so as to prevent power supply noise generated by the data input/output circuit 40 from propagating to other circuit blocks, the exclusively used power supply electric potentials VDDQ and VSS can be used for the data input/output circuit 40.

In some embodiments of the disclosure, a calibration terminal ZQ is coupled to the calibration circuit 41. In some embodiments of the disclosure, the calibration terminal ZQ is configured to be coupled to a calibration impedance RZQ that is external to the semiconductor device 10. In some embodiments of the disclosure, the calibration circuit 41 is configured to be coupled to a calibration impedance RZQ that is included in the semiconductor device, for example, one or more internal on-die calibration impedances RZQs.

When activated by a calibration signal CMDSB, the calibration circuit 41 carries out a calibration operation by referencing the impedances of one or more calibration impedances RZQ (on-die calibration impedances and/or external calibration impedances) and the reference electric potential VREF. An impedance code ZQCODE determined by the calibration operation is supplied to the data input/output circuit 40, and the impedance of data driver circuits included in data output buffer circuits of the data input/output circuit 40 is thus determined. Moreover, the calibration circuit 41 is reset by the reset signal ZQRST.

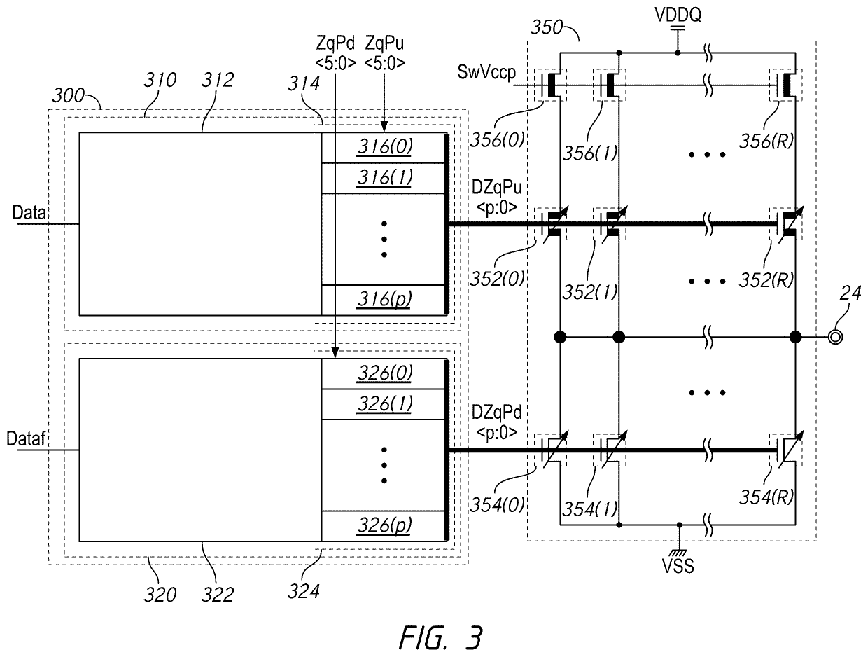

FIG. 3 is a diagram of a predriver circuit 300 and data output buffer circuit 350 according to an embodiment of the disclosure. The predriver circuit 300 and the data output buffer circuit 350 are included in a data input/output circuit in some embodiments. For example, in some embodiments of the disclosure, the predriver circuit 300 and the data output buffer circuit 350 are included in data input/output circuit 40 of FIG. 2.

The predriver circuit 300 includes a pullup predriver circuit 310 and a pulldown predriver circuit 320.

The pullup predriver circuit 310 provides a pullup driver code DZqPu to pullup data driver circuits 352 of the data output buffer circuit 350. The pullup driver code DZqPu is a multibit code that includes p+1 bits <p:0> (p is a number that is greater than or equal to zero). The bits of the pullup driver code DzqPu have logic levels based on the ZQ pullup impedance code ZqPu and the DATA signal provided to pullup predriver circuit 310. The ZQ pullup impedance code ZqPu is a multibit code. In some embodiments of the disclosure, the ZQ pullup impedance code ZqPu includes p+1 bits <p:0>. The ZQ pullup impedance code ZqPu may be included in the impedance code ZQCODE provided by a calibration circuit (e.g., calibration circuit 41 of FIG. 1). The pullup driver code DzqPu sets adjustable impedances of the pullup data driver circuits 352 and activates the pullup data driver circuits 352 to drive a high logic level voltage (e.g., VDDQ) on the data input/output terminal 24 when the DATA signal is active (e.g., active high logic level). The DATA signal represents read data that is read from a memory array. The pullup predriver circuit 310 includes a data predriver circuit 312 and pullup driver logic 314. The data predriver circuit 312 drives the DATA signal to the pullup driver logic 314. The DATA signal is used with the ZQ pullup impedance code ZqPu by pullup driver logic stages 316 to provide the pullup driver code DzqPu to the data output buffer circuit 350. In some embodiments of the disclosure, the pullup driver logic 314 includes p+1 pullup driver logic stages 316.

The pulldown predriver circuit 320 provides a pulldown driver code DZqPd to pulldown data driver circuits 354 of the data output buffer circuit 350. The pulldown driver code DZqPd is a multibit code that includes p+1 bits <p:0>. The bits of the pulldown driver code DZqPd have logic levels based on the ZQ pulldown impedance code ZqPd and the DATAf signal provided to pulldown predriver circuit 320. The pulldown driver code DzqPu sets adjustable impedances of the pulldown data driver circuits 354 and activates the pulldown data driver circuits 354 to drive a low logic level voltage (e.g., VSS) on the data input/output terminal 24 when the DATAf signal is active (e.g., active high logic level). The DATAf signal represents the read data that is read from a memory array and has a complementary logic level to the DATA signal. The pulldown predriver circuit 320 includes a data predriver circuit 322 and pulldown driver logic 324. The data predriver circuit 322 drives the DATAf signal to the pulldown driver logic 324. The DATAf signal is used with the ZQ pulldown impedance code ZqPd by pulldown driver logic stages 326 to provide the pulldown driver code DZqPd to the data output buffer circuit 350. In some embodiments of the disclosure, the pulldown driver logic 324 includes p+1 pulldown driver logic stages 326.

The data output buffer circuit 350 includes pullup data driver circuits 352(0)-352(R) and pulldown data driver circuits 354(0)-354(R) coupled to the data input/output terminal 24 (R is a number that is greater than or equal to zero). The pullup data driver circuits 352 are coupled to driver activation circuits 356. When activated by an active activation signal SwVccp (e.g., active high logic level), the driver activation circuits 356(0)-356(R) are conductive to provide the supply voltage VDDQ to the pullup data driver circuits 352. The pullup data driver circuits 352 receive the pullup driver code DZqPu from the pullup predriver circuit 310.

As previously described, when activated by an active pullup driver code DZqPu, the pullup data driver circuits 352 provide an impedance on the data input/output terminal 24 that is set by the pullup driver code DZqPu and drive a high logic level voltage (e.g., VDDQ). In some embodiments, the driver activation circuits 356 include n-channel transistors. The n-channel transistors of the driver activation circuits 356 are thick film transistors in some embodiments. The pullup data driver circuits 352 include n-channel transistors in some embodiments. In some embodiments, the n-channel transistors of the pullup data driver circuits 352 are low threshold voltage transistors.

The pulldown data driver circuits 354 are coupled to the data input/output terminal 24 and a reference voltage VSS (e.g., ground). The pulldown data driver circuits 354 receive the pulldown driver code DZqPd from the pulldown predriver circuit 320. As previously described, when activated by an active pulldown driver code DZqPd, the pulldown data driver circuits 354 provide an impedance on the data input/output terminal 24 that is set by the pulldown driver code DZqPd and drive a low logic level voltage (e.g., VSS). The pulldown data driver circuits 354 include n-channel transistors in some embodiments.

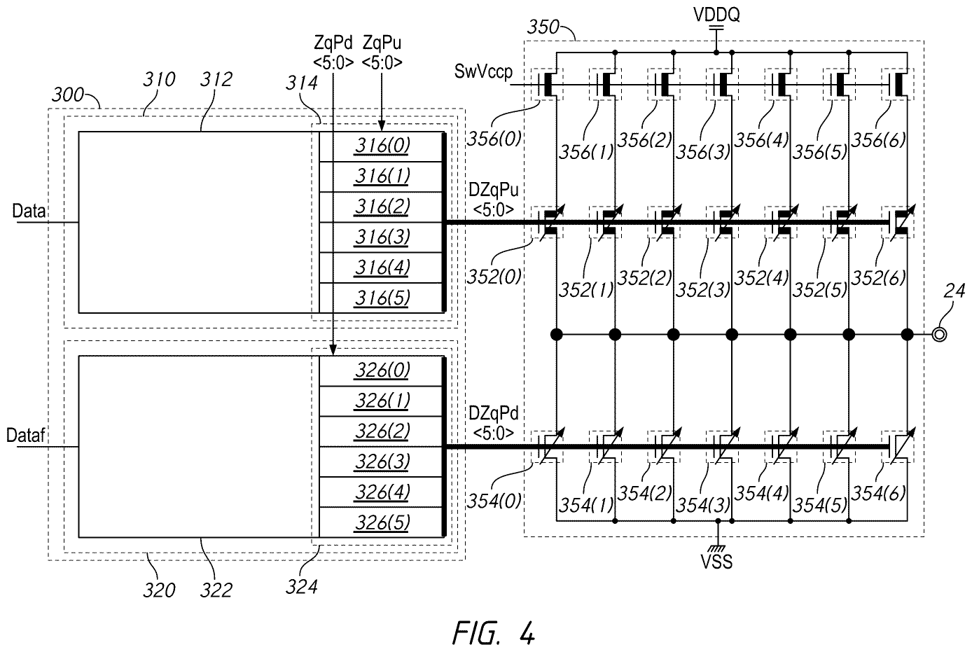

FIG. 4 is a diagram of the predriver circuit 300 and data output buffer circuit 350 according to an embodiment of the disclosure. The predriver circuit 300 and the data output buffer circuit 350 of FIG. 4 is an example of the predriver circuit 300 and data output buffer circuit 350 of FIG. 3 where p=5 and R=6. Circuits previously described with reference to FIG. 3 will be referenced in FIG. 4 using the same reference number.

With p=5, the pullup driver code DZqPu, pulldown driver code DZqPd, ZQ pullup impedance code ZqPu, and ZQ pulldown impedance code ZqPd each include 6 bits. Additionally, the pullup driver logic 314 includes 6 pullup driver logic stages 316(0)-(5) and the pulldown driver logic 324 includes 6 pulldown driver logic stages 326(0)-(5). With R=6, the data output buffer circuit 350 includes 7 driver activation circuits 356(0)-356(6), 7 pullup data driver circuits 352(0)-352(6), and 7 pulldown data driver circuits 354(0)-354(6).

Operation of the example predriver circuit 300 and data output buffer circuit 350 of FIG. 4 is the same as previously described for the predriver circuit 300 and data output buffer circuit 350 of FIG. 3.

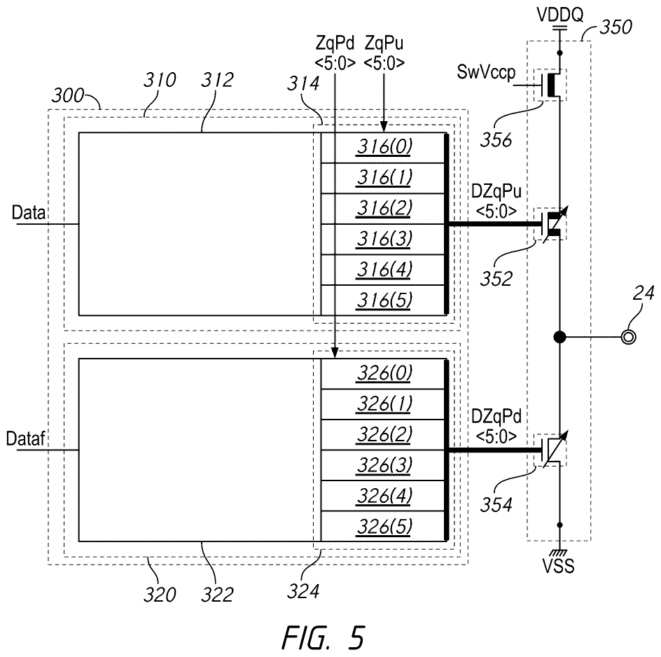

FIG. 5 is a diagram of the predriver circuit 300 and data output buffer circuit 350 according to an embodiment of the disclosure. The predriver circuit 300 and the data output buffer circuit 350 of FIG. 5 is an example of the predriver circuit 300 and data output buffer circuit 350 of FIG. 3 where p=5 and R=0. Circuits previously described with reference to FIG. 3 will be referenced in FIG. 5 using the same reference number.

With p=5, the pullup driver code DZqPu, pulldown driver code DZqPd, ZQ pullup impedance code ZqPu, and ZQ pulldown impedance code ZqPd each include 6 bits. Additionally, the pullup driver logic 314 includes 6 pullup driver logic stages 316(0)-(5) and the pulldown driver logic 324 includes 6 pulldown driver logic stages 326(0)-(5). With R=0, the data output buffer circuit 350 includes 1 driver activation circuit 356, 1 pullup data driver circuit 352, and 1 pulldown data driver circuit 354.

Operation of the example predriver circuit 300 and data output buffer circuit 350 of FIG. 5 is the same as previously described for the predriver circuit 300 and data output buffer circuit 350 of FIG. 3.

In the embodiment of FIG. 4, the data output buffer circuit 350 includes 7 legs, and the replica can have a resistance 7 times a desired driver strength. Each leg including a respective pullup data driver circuit 352, pulldown data driver circuit 354, and driver activation circuit 356. Embodiments of the disclosure are not limited to the specific example of FIG. 4, however. In some embodiments, the number of legs of the data output buffer circuit 350 can be reduced to reduce terminal capacitance. For example, the data output buffer circuit 350 may be reduced to 3 legs, and the replica may have a resistance 3 times a desired driver strength. In some embodiments, for example, the embodiment of FIG. 5, the data output buffer circuit 350 may be reduced to 1 leg, and the replica may have a resistance 1 time a desired driver strength. In such an example, the output buffer is simplified and the effect of reducing the terminal capacitance can be expected. In some embodiments, the calibration impedance RZQ can be increased to make it less susceptible to external factors. For example, the data output buffer circuit may be increased to 10 legs, and the replica may have a resistance 10 times the desired driver strength.

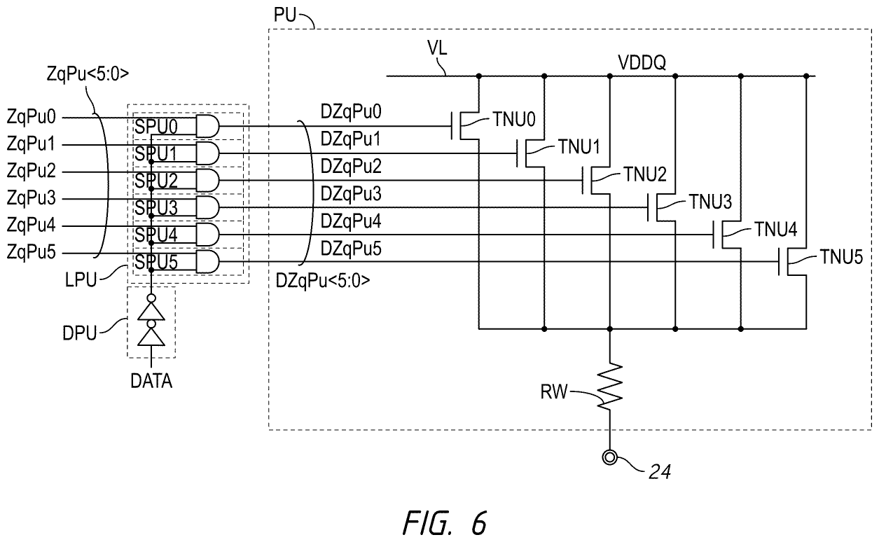

FIG. 6 is a circuit diagram of a pullup data driver circuit PU, pullup driver logic LPU, and data predriver circuit DPU according to an embodiment of the disclosure. The pullup data driver circuit PU, pullup driver logic LPU, and data predriver circuit DPU may be included in one or more of the pullup data driver circuits 352, pullup driver logic 314, and data predriver circuit 312 of FIGS. 3-5 in some embodiments of the disclosure.

The pullup data driver circuit PU includes six N-channel-type transistors TNU0 to TNU5 that are coupled in parallel with one another and coupled to a high resistance wiring circuit RW. The drains of the transistors TNU0 to TNU5 are commonly coupled to a power supply wiring VL for supplying a power supply electric potential VDDQ, and the sources of the transistors TNU0 to TNU5 are coupled to the data input/output terminal 24 through the high resistance wiring circuit RW. The high resistance wiring circuit RW forms a resistance that is in some embodiments of the disclosure made of a tungsten wire or the like. In some embodiments of the disclosure, the resistance of the high resistance wiring circuit RW is about 120Ω. Embodiments of the disclosure are not limited to the specific resistance, however.

Respective bits DZqPu0 to DZqPu5 forming a pullup driver code DZqPu<5:0> are respectively supplied to the gate electrodes of the transistors TNU0 to TNU5. Thus, the six transistors TNU0 to TNU5 are controlled so as to be individually turned on/off based upon the value of the pullup driver code DZqPu. As shown in FIG. 6, the pullup driver code DZqPu may be obtained by logically synthesizing the respective bits of the ZQ pullup impedance code ZqPu<5:0> and the internal data signal DATA by using an AND gate circuit. Thus, in the case when the internal data signal DATA represents a low level, all the transistors TNU0 to TNU5 are turned off since all the bits DZqPu0 to DZqPu5 forming the pullup driver code DZqPu become the low level irrespective of the value of the ZQ pullup impedance code ZqPu. On the other hand, in the case when the internal data signal DATA represents a high level, since the value of the ZQ pullup impedance code ZqPu, as it is, forms the value of the pullup driver code DZqPu so that some of the transistors TNU0 to TNU5 are turned on. When turned on, the parallel coupled transistors TNU provide an impedance that is added to the impedance of the resistance of the high resistance wiring circuit RW. By turning on one or more of the transistors TNU, the impedance provided by the pullup data driver circuit PU when activated to drive a high logic level voltage (e.g., VDDQ) to the data input/output terminal 24 may be adjusted.

In this case, a ratio (W/L ratio) between the channel width (W) and the channel length (L) of the transistors TNU0 to TNU5, that is, a current supplying capability, is weighted by using a power of 2. More specifically, supposing that the W/L ratio of the transistor TNU0 is 1WLnu, the W/L ratio of the transistor TNUk (k=0 to 5) is designed to be set to 2k×WLnu. Thus, the impedance of the pullup data driver circuit PU can be adjusted in 64 stages at maximum.

The data predriver circuit DPU receives the DATA signal and drives the DATA signal to the pullup driver logic LPU. The pullup driver logic LPU also receives the ZQ pullup impedance code ZqPu. The pullup driver logic LPU includes pullup driver logic stages SPU0-SPU5. Each pullup driver logic stage SPU provides one bit of the multibit pullup driver code DZqPu to a respective transistor TNU. In some embodiments of the disclosure, a pullup driver logic stage SPU includes an AND logic gate that receives one bit of the ZQ pullup impedance code ZqPu and further receives the DATA signal from the data predriver circuit DPU. The one bit of the multibit pullup driver code DZqPu provided by a pullup driver logic stage SPU result from an AND logic operation of the one bit of the ZQ pullup impedance code ZqPu and the DATA signal.

The adjustable impedance of the pullup data driver circuit PU provided to the data input/output terminal 24 when the transistors of the pullup data driver circuit PU are activated to drive a high logic level voltage can be set using the ZQ pullup impedance code ZqPu.

Embodiments of the disclosure include pullup data driver circuits PU having greater or fewer transistors TNU than included in the example pullup data driver circuit PU of FIG. 6. Additionally, embodiments of the disclosure are not limited to the specific number of pullup driver logic stages SPU and/or the specific number of bits included in the multibit pullup driver code DZqPu described with reference to FIG. 6.

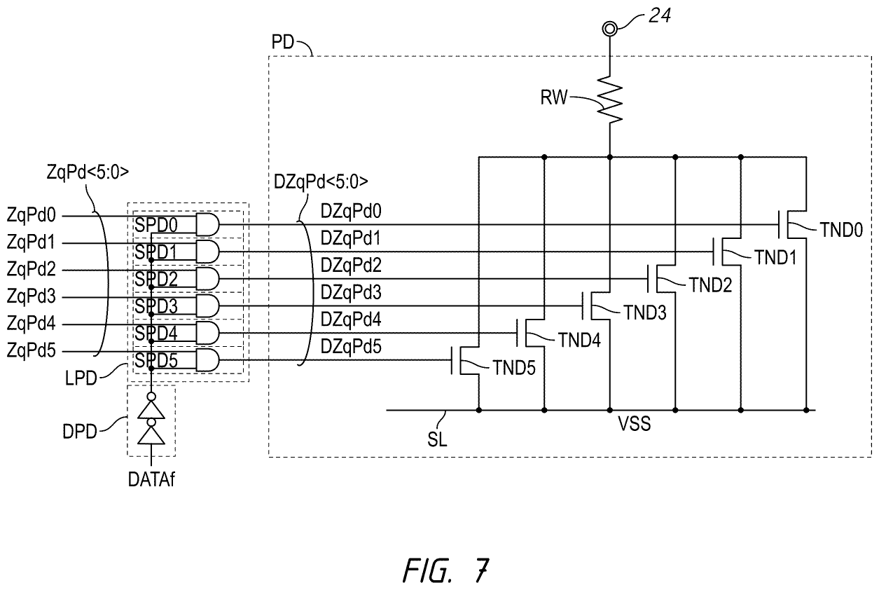

FIG. 7 is a circuit diagram of a pulldown data driver circuit PD, pulldown driver logic LPD, and data predriver circuit DPD according to an embodiment of the disclosure. The pulldown data driver circuit PD, pulldown driver logic LPD, and data predriver circuit DPD may be included in one or more of the pulldown data driver circuits 354, pulldown driver logic 324, and data predriver circuit 322 of FIGS. 3-5 in some embodiments of the disclosure.

The pulldown data driver circuit PD includes six N-channel-type transistors TND0 to TND5 that are coupled in parallel with one another and coupled to a high resistance wiring circuit RW. The drains of the transistors TND0 to TND5 are commonly coupled to a power supply wiring SL for supplying a reference electric potential VSS, and the sources of the transistors TND0 to TND5 are coupled to the data input/output terminal 24 through the high resistance wiring circuit RW. The high resistance wiring circuit RW forms a resistance that is in some embodiments of the disclosure made of a tungsten wire or the like. In some embodiments of the disclosure, the resistance of the high resistance wiring circuit RW is about 120Ω. Embodiments of the disclosure are not limited to the specific resistance, however.

Respective bits DZqPd0 to DZqPd5 forming a pulldown driver code DZqPd<5:0> are respectively supplied to the gate electrodes of the transistors TND0 to TND5. Thus, the six transistors TND0 to TND5 are controlled so as to be individually turned on/off based upon the value of the pulldown driver code DZqPd. As shown in FIG. 7, the pulldown driver code DZqPd may be obtained by logically synthesizing the respective bits of the ZQ pulldown impedance code ZqPd<5:0> and the internal data signal DATAf by using an AND gate circuit. The internal data signal DATAf has a logic level that is complementary to the internal data DATA. In the case when the internal data signal DATAf represents a low level, all the transistors TND0 to TND5 are turned off since all the bits DZqPd0 to DZqPd5 forming the pulldown driver code DZqPd become the low level irrespective of the value of the ZQ pulldown impedance code ZqPd. On the other hand, in the case when the internal data signal DATAf represents a high level, since the value of the ZQ pulldown impedance code ZqPd, as it is, forms the value of the pulldown driver code DZqPd so that some of the transistors TND0 to TND5 are turned on. When turned on, the parallel coupled transistors TND provide an impedance that is added to the impedance of the resistance of the high resistance wiring circuit RW. By turning on one or more of the transistors TND, the impedance provided by the pulldown data driver circuit PD when activated to drive a low logic level voltage (e.g., VSS) to the data input/output terminal 24 may be adjusted.

In this case, a ratio (W/L ratio) between the channel width (W) and the channel length (L) of the transistors TND0 to TND5, that is, a current supplying capability, is weighted by using a power of 2. More specifically, supposing that the W/L ratio of the transistor TND0 is 1WLnu, the W/L ratio of the transistor TNDk (k=0 to 5) is designed to be set to 2k×WLnu. Thus, the impedance of the pulldown data driver circuit PD can be adjusted in 64 stages at maximum.

The data predriver circuit DPD receives the DATAf signal and drives the DATAf signal to the pulldown driver logic LPD. The pulldown driver logic LPD also receives the ZQ pulldown impedance code ZqPd. The pulldown driver logic LPD includes pulldown driver logic stages SPD0-SPD5. Each pulldown driver logic stage SPD provides one bit of the multibit pulldown driver code DZqPd to a respective transistor TND. In some embodiments of the disclosure, a pulldown driver logic stage SPD includes an AND logic gate that receives one bit of the ZQ pulldown impedance code ZqPd and further receives the DATAf signal from the data predriver circuit DPD. The one bit of the multibit pulldown driver code DZqPd provided by a pulldown driver logic stage SPD result from an AND logic operation of the one bit of the ZQ pulldown impedance code ZqPd and the DATAf signal.

The adjustable impedance of the pulldown data driver circuit PD provided to the data input/output terminal 24 when the transistors of the pulldown data driver circuit PD are activated to drive a low logic level voltage can be set using the ZQ pulldown impedance code ZqPd.

Embodiments of the disclosure include pulldown data driver circuits PD having greater or fewer transistors TND than included in the example pulldown data driver circuit PD of FIG. 7. Additionally, embodiments of the disclosure are not limited to the specific number of pulldown driver logic stages SPD and/or the specific number of bits included in the multibit pulldown driver code DZqPd described with reference to FIG. 7.

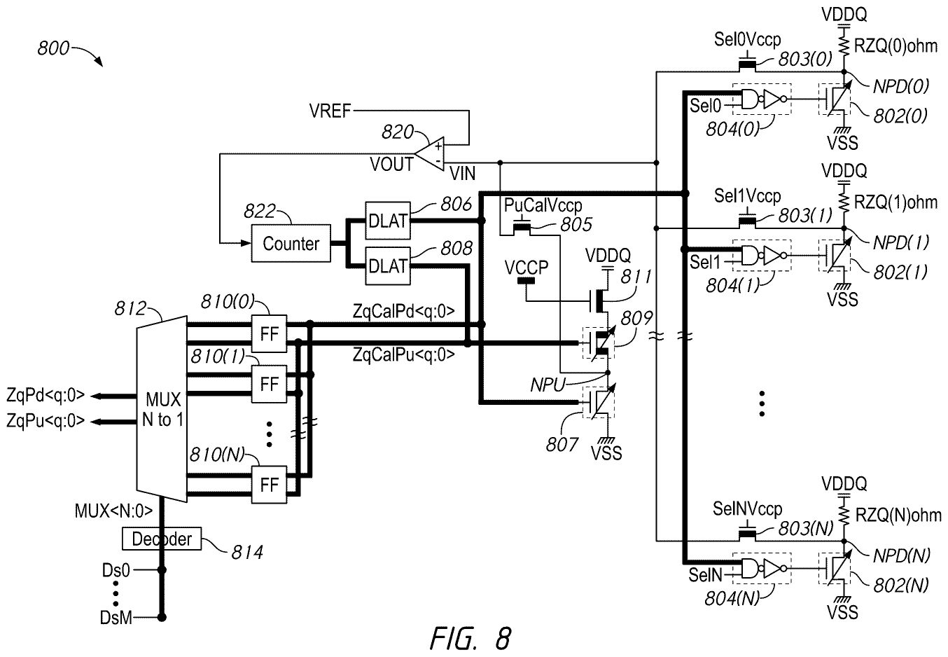

FIG. 8 is a diagram of a calibration circuit 800 according to an embodiment of the disclosure. In some embodiments of the disclosure the calibration circuit 800 may be included in calibration circuit 41 of FIG. 2.

The calibration circuit 800 includes calibration pulldown driver circuits 802(0)-802(N) that are configured to be coupled to a respective calibration impedance RZQ(0)-RZQ(N), where N is a number that is greater than or equal to zero.

As previously described, in some embodiments of the disclosure, the calibration impedance RZQ is included in the semiconductor device. Calibration impedances that are included in each semiconductor device may be referred to as “on-die” calibration impedances. On-die calibration impedances may be formed in semiconductor structures that are included in the semiconductor device. In some embodiments of the disclosure, the calibration impedance RZQ is an external circuit provided on an external substrate and is coupled to a terminal ZQ that is configured to be coupled to an external circuit. In some embodiments of the disclosure, each calibration impedance RZQ is coupled to a respective terminal ZQ.

The calibration pulldown driver circuits 802 are coupled to a reference voltage, for example, ground, and provide an impedance that is adjustable. In some embodiments of the disclosure, each of the calibration pulldown driver circuits 802 include a pulldown data driver circuit having an impedance that is adjustable as shown in and described with reference to FIG. 7. Each of the calibration pulldown driver circuits 802 is coupled to a respective selection circuit 804(0)-804(N) that provides a pulldown calibration code ZqCalPd when a respective selection signal SelN is active (e.g., active high logic level). The selection signal SelN may be provided by a command decoder (e.g., command decoder 34 of FIG. 2; included in calibration control signals ZQCTL). For example, The pulldown calibration code ZqCalPd provided by the selection circuit 804 sets an impedance of the respective calibration pulldown driver circuit 802. The pulldown calibration code ZqCalPd includes q+1 bits (q is a number greater than or equal to zero). The pulldown calibration code ZqCalPd is provided by a pulldown code latch circuit 806. In some embodiments of the disclosure the pulldown code latch circuit 806 includes a D-latch circuit.

The ZqCalPd code is also provided to a replica pulldown driver circuit 807. The replica pulldown driver circuit 807 has an adjustable impedance that is set by the ZqCalPd code. The replica pulldown driver circuit 807 has the same impedance characteristics as the calibration pulldown driver circuits 802. Additionally, both the replica pulldown driver circuit 807 and the calibration pulldown driver circuits 802 have the same impedance characteristics as pulldown data driver circuits included in a data output buffer circuit (e.g., pulldown data driver circuit 354 of FIG. 3). As a result, a replica pulldown driver circuit 807 will have the same impedance as calibration pulldown driver circuits 802 when the same ZqCalPd code is provided to the circuits. Likewise, pulldown data driver circuits included in a data output buffer circuit will have the same impedance as the replica pulldown driver circuit 807 (and as the calibration pulldown driver circuits 802) when the same ZqCalPd code is provided to the circuits.

The calibration circuit 800 further includes a voltage comparator 820. The voltage comparator 820 provides an output voltage VOUT having a voltage based on the voltage of an input voltage VIN relative to a reference electric potential VREF. For example, the voltage comparator 820 provides VOUT having a relatively high voltage when VIN is less than VREF, and provides VOUT having a relatively low voltage when VIN is greater than VREF. In some embodiments, the voltage of the reference electric potential VREF is ½ of a supply voltage VDDQ. The VREF voltage is provided to an input of the voltage comparator 820. The VREF voltage may be provided by an internal power supply generation circuit (e.g., internal power supply generation circuit 38 of FIG. 2).

The output voltage VOUT is provided to a counter circuit 822 that provides a multibit count value to the pulldown code latch circuit 806 and to a pullup code latch circuit 808. In some embodiments of the disclosure, the count value includes q+1 bits. The counter circuit 822 changes the count value based on the voltage of VOUT. For example, when VOUT is a relatively high voltage (e.g., VDDQ), the counter circuit 822 increases the count value and when VOUT is a relatively low voltage (e.g., ground), the counter circuit 822 decreases the count value.

The input voltage VIN is provided from pulldown calibration nodes NPD(0)-NPD(N) that are coupled to the input of the voltage comparator 820 through respective pulldown selection switches 803(0)-803(N). Activation of the switches 803(0)-803(N) are controlled by a respective switch control signal Sel0Vccp-SelNVccp. The switch control signals Sel0Vccp-SelNVccp may be provided, for example, by a command decoder (e.g., command decoder 34 of FIG. 2; included in calibration control signals ZQCTL). When a pulldown selection switch 803 is activated, the voltage of the respective pulldown calibration node NPD is provided as the input voltage VIN to the voltage comparator 820. In some embodiments of the disclosure, the pulldown selection switches 803 are thick film n-channel transistors.

The calibration circuit 800 also includes a replica pullup driver circuit 809 coupled to the replica pulldown driver circuit 807 at a pullup calibration node NPU. The replica pullup driver circuit 809 is also coupled to a replica driver activation circuit 811. The replica pullup driver circuit 809 has an adjustable impedance that is set by a ZqCalPu code. In some embodiments of the disclosure, the replica pullup driver circuit 809 includes a pullup data driver circuit having adjustable impedance as shown in and described with reference to FIG. 6. The replica driver activation circuit 811 has the same transistor characteristics as a driver activation circuit included in a data output buffer circuit (e.g., driver activation circuit 356 of FIG. 3). The replica pullup driver circuit 809 has the same impedance characteristics as pullup data driver circuits included in a data output buffer circuit (e.g., pullup data driver circuit 352 of FIG. 3). As a result, pullup data driver circuits included in a data output buffer circuit will have the same impedance as the replica pullup driver circuit 809 when the same ZqCalPu code is provided to the circuits. The replica driver activation circuit 811 is coupled to a power supply voltage VCCP that causes the replica driver activation circuit 811 to be activated to provide the power supply voltage VDDQ to the replica pullup driver circuit 809. The power supply voltage VCCP is greater than the power supply voltage VDDQ. In some embodiments of the disclosure, the replica pullup driver circuit 809 includes a low threshold voltage n-channel transistor. In some embodiments of the disclosure, the replica driver activation circuit 811 includes a thick film n-channel transistor.

The pullup calibration node NPU is coupled through pullup selection switch 805 to the input of the voltage comparator 820. Activation of the switch 805 is controlled by switch control signal PuCalVccp. The switch control signal PuCalVccp may be provided, for example, by a command decoder (e.g., command decoder 34 of FIG. 2; included in calibration control signals ZQCTL). When the pullup selection switch 805 is activated, the voltage of the pullup calibration node NPU is provided as the input voltage VIN to the voltage comparator 820. In some embodiments of the disclosure, the pullup selection switch 805 is a thick film n-channel transistor.

The pulldown calibration code ZqCalPd and the pullup calibration code ZqCalPu are multibit codes. In some embodiments, the ZqCalPd code and the ZqCalPu code each have q+1 bits, that is, bits <q:0>.

The pulldown calibration code ZqCalPd and the pullup calibration code ZqCalPu are provided by the pulldown code and pulldown code latch circuits 806 and 808 to ZQ code storage circuits 810(0)-810(N). In some embodiments of the disclosure, the ZQ code storage circuits 810 include flip-flop circuits. Each of the ZQ code storage circuits 810 stores a ZqCalPd code and a ZqCalPu code for a respective calibration impedance RZQ. The ZqCalPd code and the ZqCalPu code are provided to multiplexer 812. The multiplexer 812 is controlled by multiplexer signals MUX<N:0> to provide the ZqCalPd and ZqCalPu codes from one of the ZQ code storage circuit 810 as ZQ pulldown and ZQ pullup impedance codes ZqPd and ZqPu. The MUX<N:0> signals are provided by a multiplexer decoder circuit 814 that decodes drive strength signals Ds0-DsM, where M is a number that is greater than or equal to zero. The drive strength signals Ds0-DsM may be provided by a mode register that stores drive strength settings. In some embodiments of the disclosure, mode register 14 of FIG. 2 stores drive strength settings and provides the drive strength signals Ds0-DsM to the multiplexer decoder circuit 814. The drive strength signals Ds0-DsM may be provided by a command decoder based on drive strength settings in a mode register in some embodiments. The drive strength signals Ds0-DsM in effect select which of the ZqCalPd and ZqCalPu codes stored by one of the ZQ code storage circuits 810 are provided by the multiplexer 812 as the ZqPd and ZqPu codes.

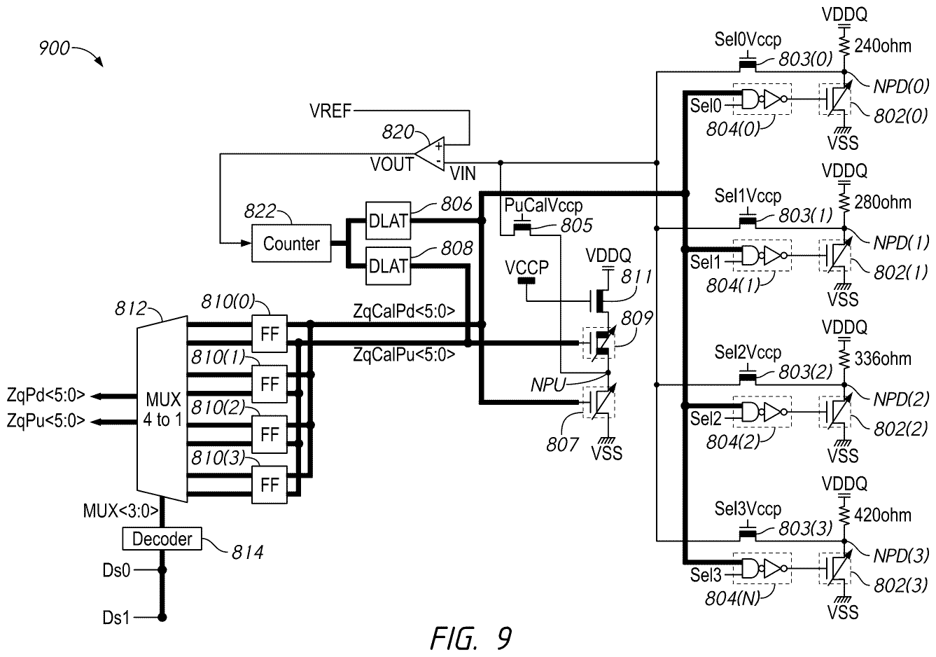

FIG. 9 is a diagram of a calibration circuit 900 according to an embodiment of the disclosure. In some embodiments of the disclosure the calibration circuit 900 may be included in calibration circuit 41 of FIG. 2.

The calibration circuit 900 is an example of the calibration circuit 800 where N=3, q=5, and M=1. With N=3, there are four calibration impedances to be set. With q=5, the pulldown and pullup calibration codes ZqCalPd and ZqCalPu both include 6-bits. With M=1, two drive strength signals Ds0 and Ds1 are used to select which of the four ZqCalPd and ZqCalPu codes are provided as the ZqPd and ZqPu codes.

For the example of FIG. 9, the values of the calibration impedances are RZQ(0)=240 ohm; RZQ(1)=280 ohm; RZQ(2)=336 ohm; and RZQ(3)=420 ohm. The values of the calibration impedances are provided by way of example, and are not intended to limit the scope of the embodiments to the particular impedance values. In embodiments where the data output buffer circuit includes seven pullup data driver circuits and seven pulldown data driver circuits, the resulting drive strengths for the calibration impedances correspond to 34.3 ohm; 40 ohm; 48 ohm; 60 ohm. In some embodiments of the disclosure, the calibration impedances RZQ(0)-RZQ(3) are included in the semiconductor device as on-die calibration impedances. For example, the on-die calibration impedances may be formed in semiconductor structures that are included in the semiconductor device. In some embodiments of the disclosure, the calibration impedances RZQ(0)-RZQ(3) are external circuit provided on the external substrate and are coupled to external ZQ terminals that are configured to be coupled to an external circuit.

In operation, impedance calibration will be performed for each of the four calibration impedances RZQ(0)-RZQ(3) and the resulting pulldown and pullup calibration codes ZqCalPd and ZqCalPu are stored in respective ZQ code storage circuits 810(0)-810(N). For example, the ZqCalPd and ZqCalPu codes for RZQ(0)=240 ohm are stored by ZQ code storage circuit 810(0), the ZqCalPd and ZqCalPu codes for RZQ(1)=280 ohm are stored by ZQ code storage circuit 810(1), and so on. After storing the ZqCalPd and ZqCalPu codes for each of the calibration impedances RZQ(0)-RZQ(3), the ZqCalPd and ZqCalPu codes for one of the calibration impedances is provided by the multiplexer 812 as the ZQ pulldown and ZQ pullup impedance codes ZqPd and ZqPu based on a drive strength setting, as represented by the drive strength signals Ds0 and Ds1.

Calibration for RZQ(0)=240 ohm will be described. Generally, the pulldown calibration code ZqCalPd is determined by setting the pulldown calibration code ZqCalPd to set the impedance of calibration pulldown driver circuit 802(0) so that the voltage of the pulldown calibration node NPD(0) is equal to the VREF voltage. The same pulldown calibration code ZqCalPd is applied to set the impedance of the replica pulldown driver circuit 807. As previously described, the replica pulldown driver circuit 807 and the calibration pulldown driver circuit 802(0) have the same impedance characteristics. As a result, the impedance of the replica pulldown driver circuit 807 and the impedance of the calibration pulldown driver circuit 802(0) are the same for the same ZqCalPd code.

The RZQ(0)=240 ohm is selected for calibration by providing an active selection signal Sel0 to activate the selection circuit 804(0) and providing an active switch control signal Sel0Vccp to activate the pulldown selection switch 803(0). With the selection circuit 804(0) activated, the calibration pulldown driver circuit 802(0) receives the pulldown calibration code ZqCalPd from the pulldown code latch circuit 806 to set the impedance of the calibration pulldown driver circuit 802(0). With the pulldown selection switch 803(0) activated, the voltage at the pulldown calibration node NPD(0) is provided to the input of the voltage comparator 820.

The output VOUT of the voltage comparator, which is based on the voltage at NPD(0) relative to the VREF voltage, causes the counter circuit 822 to change the value provided to the pulldown code latch circuit 806, and consequently, change the pulldown calibration code ZqCalPd that is received by the calibration pulldown driver circuit 802(0). For example, in some embodiments, when the voltage of NPD(0) is less than the VREF voltage, indicating that the impedance of the calibration pulldown driver circuit 802(0) is less than a target pulldown impedance, the voltage comparator 820 provides VOUT having a relatively high voltage. The relatively high voltage of VOUT causes the counter circuit 822 to increase the ZqCalPd code, which in turn when applied to the calibration pulldown driver circuit 802(0), causes the impedance of the calibration pulldown driver circuit 802(0) to increase. The increased impedance of the calibration pulldown driver circuit 802(0) causes the voltage of NPD(0) to increase. Conversely, when the voltage of NPD(0) is greater than the VREF voltage, indicating that the impedance of the calibration pulldown driver circuit 802(0) is greater than a target pulldown impedance, the voltage comparator 820 provides VOUT having a relatively low voltage. The relatively low voltage of VOUT causes the counter circuit 822 to decrease the ZqCalPd code, which in turn when applied to the calibration pulldown driver circuit 802(0), causes the impedance of the calibration pulldown driver circuit 802(0) to decrease. The decreased impedance of the calibration pulldown driver circuit 802(0) causes the voltage of NPD(0) to decrease. The ZqCalPd code continues to be changed by the counter circuit 822 until the voltage of NPD(0) is equal to the VREF voltage.

The ZqCalPd code is also provided to the replica pulldown driver circuit 807, which sets the impedance of the replica pulldown driver circuit 807 to the same impedance of the calibration pulldown driver circuit 802(0). When the target pulldown impedance of the calibration pulldown driver circuit 802(0) is set by the ZqCalPd code, the replica pulldown driver circuit 807 is also set to the target pulldown impedance. After determining the ZqCalPd code that sets the calibration pulldown driver circuit 802(0) to the target pulldown impedance, the pulldown selection switch 803(0) is deactivated by changing the switch control signal Sel0Vccp to inactive, and the selection circuit 804(0) is deactivated by changing the selection signal Sel0 to inactive.

After the ZqCalPd code is determined, the replica pulldown driver circuit 807 set to the target pulldown impedance is used to determine the ZqCalPu code to set the replica pullup driver circuit 809 to a target pullup impedance. The ZqCalPu code is determined by setting the impedance of the replica pullup driver circuit 809 so that the voltage of the pullup calibration node NPU is equal to the VREF voltage. The ZqCalPu code is provided to the replica pullup driver circuit 809 from the pullup code latch circuit 808 to set the impedance of the replica pullup driver circuit 809. The pullup selection switch 805 is activated by an active switch control signal PuCalVccp. When the pullup selection switch 805 is activated, the voltage of the pullup calibration node NPU is provided to the input of the voltage comparator 820.

The output VOUT of the voltage comparator, which is based on the voltage at NPU relative to the VREF voltage, causes the counter circuit 822 to change the value provided to the pullup code latch circuit 808, and consequently, change the pullup calibration code ZqCalPu that is received by the replica pullup driver circuit 809. For example, in some embodiments, when the voltage of NPU is less than the VREF voltage, indicating that the impedance of the replica pullup driver circuit 809 is greater than a target pullup impedance, the voltage comparator 820 provides VOUT having a relatively high voltage. The relatively high voltage of VOUT causes the counter circuit 822 to increase the ZqCalPu code, which in turn when applied to the replica pullup driver circuit 809, causes the impedance of the replica pullup driver circuit 809 to decrease. The decreased impedance of the replica pullup driver circuit 809 causes the voltage of NPU to increase. Conversely, when the voltage of NPU is greater than the VREF voltage, indicating that the impedance of the replica pullup driver circuit 809 is less than a target pullup impedance, the voltage comparator 820 provides VOUT having a relatively low voltage. The relatively low voltage of VOUT causes the counter circuit 822 to decrease the ZqCalPu code, which in turn when applied to the replica pullup driver circuit 809, causes the impedance of the replica pullup driver circuit 809 to increase. The increased impedance of the replica pullup driver circuit 809 causes the voltage of NPU to decrease. The ZqCalPu code continues to be changed by the counter circuit 822 until the voltage of NPU is equal to the VREF voltage.

After determining the ZqCalPu code that sets the replica pullup driver circuit 809 to the target pullup impedance, the pullup selection switch 805 is deactivated by changing the switch control signal PuCalVccp to inactive.

The ZqCalPd code that sets the calibration pulldown driver circuit 802(0) to the target pulldown impedance and the ZqCalPu code that sets the replica pullup driver circuit 809 to the target pullup impedance are both stored by the ZQ code storage circuit 810(0). The target pulldown impedance and the target pullup impedance may be different for each of the calibration impedances RZQ.

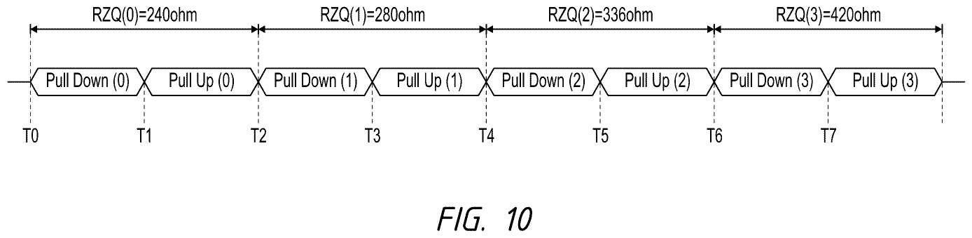

The calibration operation for each of the remaining RZQs is performed as described for the RZQ(0)=240 ohm. For example, FIG. 10 is a timing diagram for determining pulldown and pullup calibration codes ZqCalPd and ZqCalPu according to an embodiment of the disclosure. FIG. 10 is described with reference to RZQ(0)=240 ohm, RZQ(1)=280 ohm, RZQ(2)=336 ohm, and RZQ(3)=420 ohm. Following time T0, the ZqCalPd code for RZQ(0)=240 ohm is determined, and following time T1, the ZqCalPu code for RZQ(0)=240 ohm is determined. The determined ZqCalPd and ZqCalPu codes for RZQ(0)=240 ohm are stored by the ZQ code storage circuit 810(0). Following time T2, the ZqCalPd code for RZQ(1)=280 ohm is determined, and following time T3, the ZqCalPu code for RZQ(1)=280 ohm is determined. The determined ZqCalPd and ZqCalPu codes for RZQ(1)=280 ohm are stored by the ZQ code storage circuit 810(1). Following time T4, the ZqCalPd code for RZQ(2)=336 ohm is determined, and following time T5, the ZqCalPu code for RZQ(2)=336 ohm is determined. The determined ZqCalPd and ZqCalPu codes for RZQ(2)=336 ohm are stored by the ZQ code storage circuit 810(2). Following time T6, the ZqCalPd code for RZQ(3)=420 ohm is determined, and following time T7, the ZqCalPu code for RZQ(3)=420 ohm is determined. The determined ZqCalPd and ZqCalPu codes for RZQ(3)=420 ohm are stored by the ZQ code storage circuit 810(3).

As previously described, the drive strength signals are used to select the ZqCalPd and ZqCalPu codes for one of the RZQs to be provided by the multiplexer 812 as the ZqPd and ZqPu codes. For example, in some embodiments of the disclosure, when Ds0 and Ds1 are 0, the multiplexer decoder circuit 814 decodes Ds0 and Ds1 to provide multiplexer signals MUX<3:0> to control the multiplexer 812 to provide the ZqCalPd and ZqCalPu codes from the ZQ code storage circuit 810(0) as the ZqPd and ZqPu codes. When Ds0 is 1 and Ds1 is 0, the multiplexer decoder circuit 814 decodes Ds0 and Ds1 to provide multiplexer signals MUX<3:0> to control the multiplexer 812 to provide the ZqCalPd and ZqCalPu codes from the ZQ code storage circuit 810(1) as the ZqPd and ZqPu codes. Likewise, when Ds0 is 0 and Ds1 is 1, the multiplexer 812 provides ZqCalPd and ZqCalPu codes from the ZQ code storage circuit 810(2) as the ZqPd and ZqPu codes, and when Ds0 and Ds1 are 1, the multiplexer 812 provides ZqCalPd and ZqCalPu codes from the ZQ code storage circuit 810(3) as the ZqPd and ZqPu codes. The drive strength signals Ds0 and Ds1 may be provided by a mode register, which stores the drive strength setting that selects a drive strength for the data driver circuits included in data output buffer circuits of a data input/output circuit. In some embodiments, the drive strength signals Ds0 and Ds1 are provided by a command decoder, for example, that reads drive strength settings stored by the mode register.

In some embodiments, such as for low power wide input/output (LPW) type memory, including on-die RZQs may be desirable. In such embodiments, since LPW does not terminate the interface, small driver strength is not required, and four types of drive strengths, for example, 34.3 ohm/40 ohm/48 ohm/60 ohm are sufficient. Three types may also be sufficient. The RZQs for RZQ(0)=240 ohm, RZQ(1)=280 ohm, RZQ(2)=336 ohm, RZQ(3)=420 ohm provide drive strengths of 34.3 ohm/40 ohm/48 ohm/60 ohm when the ZqPd and ZqPu codes are applied to data driver circuits of a data output buffer circuit including 7 legs (e.g., data output buffer 350 of FIG. 4). That is, ZqPd and ZqPu codes setting a 240 ohm data driver circuit impedance divided by 7 legs results in a 34.3 ohm drive strength; ZqPd and ZqPu codes setting a 280 ohm data driver circuit impedance divided by 7 legs results in a 40 ohm drive strength; ZqPd and ZqPu codes setting a 336 ohm data driver circuit impedance divided by 7 legs results in a 48 ohm drive strength; ZqPd and ZqPu codes setting a 420 ohm data driver circuit impedance divided by 7 legs results in a 60 ohm drive strength. In this way, resistors with the required number of driver strengths are arranged with a resistance value of 1 unit that will give the desired resistance in 7 units.

The ZqPd and ZqPu codes generated as previously described contains driver strength selection information. Therefore, there is no need to decode the driver strength information in the predriver section. As a result, the data path can be configured with one path as shown in FIGS. 3-5.

Embodiments of the disclosure can be implemented with any resistance value and any driver strength number. Any resistance value can be specified, not just in 240 ohm increments. This is because the value and number of built-in ZQ resistors can be designed for any impedance values.

In some embodiments of the disclosure, by simplifying the predriver portion of the DQ output circuit, it is possible to design a low area/low current consumption by minimizing the gate length, and to design a high speed circuit with minimal current increase even when the fan-out is reduced.

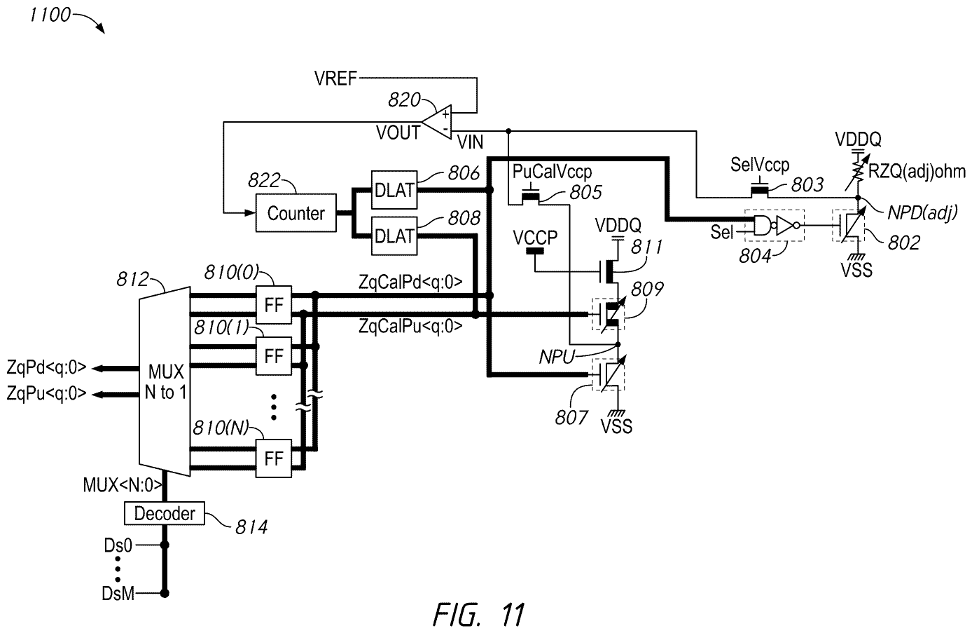

FIG. 11 is a diagram of a calibration circuit 1100 according to an embodiment of the disclosure. In some embodiments of the disclosure the calibration circuit 1100 may be included in calibration circuit 41 of FIG. 2. Circuits previously described with reference to FIG. 8 will be referenced in FIG. 11 using the same reference number.

The calibration circuit 800 of FIG. 8 was previously described as including calibration pulldown driver circuits 802(0)-802(N) configured to be coupled to a respective calibration impedances RZQ(0)-RZQ(N), where N is a number that is greater than or equal to zero. The calibration circuit 1100 includes a calibration pulldown driver circuit 802, pulldown selection switch 803, and selection circuit 804 configured to be coupled to an adjustable calibration impedance RZQ(adj). In some embodiments of the disclosure, the adjustable calibration impedance RZQ(adj) is included in the semiconductor device as on-die calibration impedances. In some embodiments of the disclosure, the adjustable calibration impedance RZQ(adj) is an external circuit provided on the external substrate and are coupled to an external ZQ terminal.

The calibration circuit 1100 can be used to determine pulldown calibration code ZqCalPd and pullup calibration code ZqCalPu for different calibration impedances provided by the adjustable calibration impedance RZQ(adj). For example, in some embodiments, the ZqCalPd and ZqCalPu codes for a first calibration impedance value RZQ(adj1) can be determined by performing a calibration operation as previously described, for example, with reference to FIG. 9 for an RZQ. The ZqCalPd and ZqCalPu codes determined for RZQ(adj1) are then stored in a ZQ code storage circuit 810, for example, ZQ code storage circuit 810(0). The adjustable calibration impedance RZQ(adj) is adjusted to a second calibration impedance value RZQ(adj2) and another calibration operation can be performed to determine the corresponding ZqCalPd and ZqCalPu codes for RZQ(adj2). The ZqCalPd and ZqCalPu codes determined for RZQ(adj2) are then stored in a ZQ code storage circuit 810, for example, ZQ code storage circuit 810(1). Adjusting the adjustable calibration impedance RZQ(adj), performing a calibration operation, and storing the determined ZqCalPd and ZqCalPu codes can be repeated for other calibration impedance values.

Although one adjustable calibration impedance is shown in FIG. 11, additional calibration pulldown driver circuits 802, pulldown selection switches 803, and selection circuits 804 may be added to be used for embodiments where more than one adjustable calibration impedances are coupled to the calibration circuit.

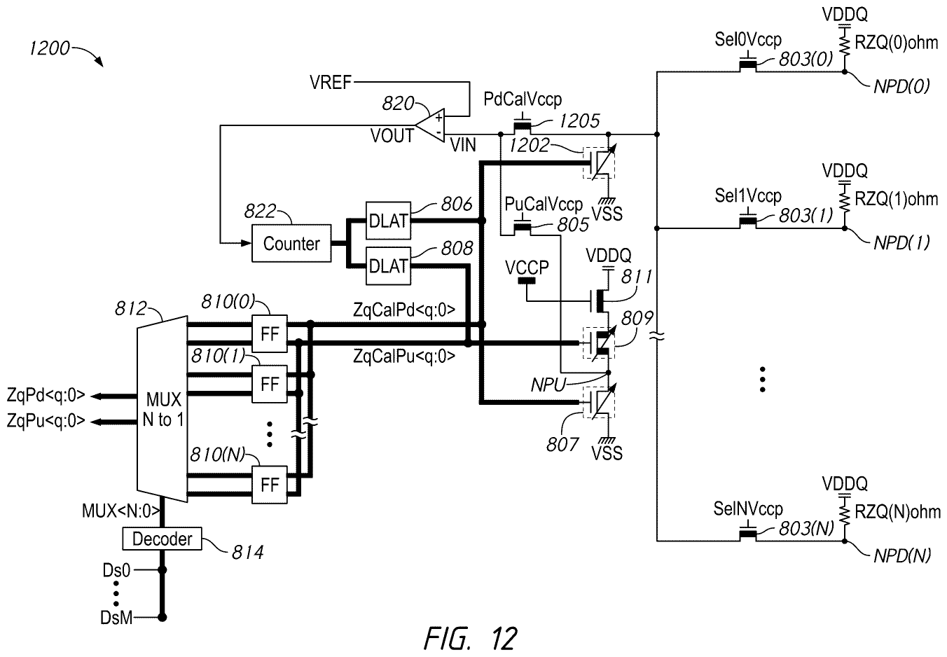

FIG. 12 is a diagram of a calibration circuit 1200 according to an embodiment of the disclosure. In some embodiments of the disclosure the calibration circuit 1200 may be included in calibration circuit 41 of FIG. 2. Circuits previously described with reference to FIG. 8 will be referenced in FIG. 12 using the same reference number.

The calibration circuit 800 of FIG. 8 was previously described as including calibration pulldown driver circuits 802(0)-802(N) configured to be coupled to a respective calibration impedances RZQ(0)-RZQ(N), where N is a number that is greater than or equal to zero. In some embodiments of the disclosure, the calibration impedances RZQ(0)-RZQ(N) are included in the semiconductor device as on-die calibration impedances. In some embodiments of the disclosure, the calibration impedances RZQ(0)-RZQ(N) are external circuit provided on the external substrate and are coupled to external ZQ terminals that are configured to be coupled to an external circuit.

The calibration circuit 1200 includes a shared calibration pulldown driver circuit 1202 and pulldown selection switches 803(0)-803(N) configured to be coupled to calibration impedances RZQ(0)-RZQ(N). A pulldown calibration switch 1205 coupled to the shared calibration pulldown driver circuit 1202 provides a conductive path from the shared calibration pulldown driver circuit 1202 to the input of the voltage comparator 820 when activated by an active switch control signal PdCalVccp. The switch control signal PdCalVccp may be provided, for example, by a command decoder (e.g., command decoder 34 of FIG. 2; included in calibration control signals ZQCTL).

The calibration circuit 1200 can be used to determine pulldown calibration code ZqCalPd and pullup calibration code ZqCalPu for the different calibration impedances RZQ(0)-RZQ(N). Rather than including a respective calibration pulldown driver circuit for each calibration impedance RZQ, for example, as described with reference to calibration circuit 800 of FIG. 8, the calibration circuit 1200 includes a shared calibration pulldown driver circuit 1202 that is used during calibration operations for each of the calibration impedances RZQ(0)-RZQ(N).

For example, to determine the ZqCalPd code for a calibration impedance RZQ(0)-RZQ(N), the pulldown calibration switch 1205 is activated by an active switch control signal PdCalVccp to provide a conductive path from the shared calibration pulldown driver circuit 1202 and the input of the voltage comparator 820. One of the calibration impedances RZQ(0)-RZQ(N) is selected for calibration by activating the respective pulldown selection switch 803. For example, RZQ(0) is selected for calibration by providing an active switch control signal Sel0Vccp to activate the pulldown selection switch 803(0). With both the pulldown selection switch 803(0) and the pulldown calibration switch 1205 activated, the voltage at the pulldown calibration node NPD(0) is provided to the input of the voltage comparator 820 for impedance calibration.

Based on the voltage at NPD(0) relative to the VREF voltage, the voltage comparator 820 provides an output VOUT that causes the counter circuit 822 to change the pulldown calibration code ZqCalPd provided by the pulldown code latch circuit 806 to the shared calibration pulldown driver circuit 1202. In some embodiments, when the voltage of NPD(0) is less than the VREF voltage, indicating that the impedance of the shard calibration pulldown driver circuit 1202 is less than a target pulldown impedance, the voltage comparator 820 provides VOUT to cause the counter circuit 822 to increase the ZqCalPd code to increase the impedance of the shared calibration pulldown driver circuit 1202. Conversely, when the voltage of NPD(0) is greater than the VREF voltage, indicating that the impedance of the shared calibration pulldown driver circuit 1202 is greater than a target pulldown impedance, the voltage comparator 820 provides VOUT to cause the counter circuit 822 to decrease the ZqCalPd code to decrease the impedance of the calibration pulldown driver circuit 1202. As the ZqCalPd code is changed and the impedance of the calibration pulldown driver circuit 1202 changes, the voltage at NPD(0) changes. The ZqCalPd code continues to be changed by the counter circuit 822 until the voltage of NPD(0) is equal to the VREF voltage.

The ZqCalPd code is also provided to the replica pulldown driver circuit 807, which sets the impedance of the replica pulldown driver circuit 807 to the same impedance of the shared calibration pulldown driver circuit 1202. When the impedance of the shared calibration pulldown driver circuit 1202 is set by the ZqCalPd code to the target pulldown impedance, the replica pulldown driver circuit 807 is also set to the target pulldown impedance.

After determining the ZqCalPd code that sets the shared calibration pulldown driver circuit 1202 to the target pulldown impedance, the pulldown selection switch 803(0) is deactivated by changing the switch control signal Sel0Vccp to inactive, and the pulldown calibration switch 1205 is deactivated by changing the switch control signal PdCalVccp to inactive.

The replica pulldown driver circuit 807, which is set to the target pulldown impedance by the ZqCalPd code that set the shared calibration pulldown driver circuit 1202 to the target pulldown impedance, is used to determine the ZqCalPu code to set the replica pullup driver circuit 809 to a target pullup impedance. The ZqCalPu code is determined by setting the pullup calibration code ZqCalPu to set the impedance of the replica pullup driver circuit 809 so that the voltage of the pullup calibration node NPU is equal to the VREF voltage. For the calibration circuit 1200, the ZqCalPu code for a calibration impedance can be determined as previously described with reference to the calibration circuit 900 of FIG. 9.

The calibration operation for each of the remaining RZQs is performed as described for the RZQ(0). After the ZqCalPd and ZqCalPu codes for a RZQ are determined, the corresponding ZqCalPd and ZqCalPu codes are stored by a respective one of the ZQ code storage circuits 810. For example, the ZqCalPd and ZqCalPu codes for RZQ(0) are stored by the ZQ code storage circuit 810(0); the ZqCalPd and ZqCalPu codes for RZQ(1) are stored by the ZQ code storage circuit 810(1); and so on with the ZqCalPd and ZqCalPu codes for RZQ(N) stored by the ZQ code storage circuit 810(N).

As previously described, the drive strength signals Ds0-DsM are used to select the ZqCalPd and ZqCalPu codes for one of the RZQs to be provided by the multiplexer 812 as the ZqPd and ZqPu codes.

It is to be appreciated that any one of the examples, embodiments or processes described herein may be combined with one or more other examples, embodiments and/or processes or be separated and/or performed amongst separate devices or device portions in accordance with the present systems, devices, and methods.

Additionally, the above discussion is intended to be merely illustrative of the present system and should not be construed as limiting the appended claims to any particular embodiment or group of embodiments. Thus, while the present systems, apparatuses, and methods have been described in particular detail with reference to example embodiments, it should also be appreciated that modifications and alternative embodiments may be devised by those having ordinary skill in the art without departing from the broader and intended spirit and scope of the present technology as set forth in the claims that follow. Accordingly, the present disclosure is to be regarded in an illustrative manner and is not intended to limit the scope of the appended claims.

1. An apparatus, comprising:
a first calibration impedance;
a second calibration impedance having an impedance that is different than the first calibration impedance;
a memory including a calibration circuit coupled to the first and second calibration impedances, the calibration circuit including a first calibration driver circuit coupled to the first calibration impedance and having a first impedance that is adjustable and set by a first calibration code, and the calibration circuit further including a second calibration driver circuit coupled to the second calibration impedance and having a second impedance that is adjustable and set by a second calibration code, the calibration circuit configured to determine the first calibration code to set the first impedance of the first calibration driver circuit to a first target impedance and to determine the second calibration code to set the second impedance of the second calibration driver circuit to a second target impedance.

2. The apparatus of claim 1 wherein the first and second calibration impedances each comprises an on-die calibration impedance included in the memory.

3. The apparatus of claim 1 wherein the first and second calibration impedances are each external to the memory and coupled to a respective terminal configured to be coupled to an external circuit.

4. The apparatus of claim 1 wherein the first calibration driver circuit comprises a first calibration pulldown driver circuit and wherein the second calibration driver circuit comprises a second calibration pulldown driver circuit.

5. The apparatus of claim 1 wherein the calibration circuit further includes a replica pulldown driver circuit and a replica pullup driver circuit.

6. The apparatus of claim 5, further comprising a data output buffer circuit including a pulldown data driver circuit and a pullup data driver circuit, the replica pulldown driver circuit having same impedance characteristics as the pulldown data driver circuit and the replica pullup driver circuit having same impedance characteristics as the pullup data driver circuit.

7. The apparatus of claim 1 wherein the calibration circuit further includes:
a first code storage circuit configured to store the first calibration code;
a second code storage circuit configured to store the second calibration code; and
a multiplexer coupled to the first code storage circuit and the second code storage circuit, the multiplexer configured to provide the first calibration code or the second calibration code as an impedance code for setting an impedance of a data driver circuit based on drive strength signals.

8. The apparatus of claim 1 wherein the calibration circuit further includes:
a voltage comparator configured to receive a reference electric potential and to receive a voltage from a calibration node and provide an output voltage based on a comparison of the reference electric potential and the voltage from the calibration node, the calibration node coupled to the first calibration impedance and the second calibration impedance; and
a counter circuit configured to provide a multibit count value that is used as the first calibration code or the second calibration code, and further configured to change the multibit count value based on the output voltage.

9. An apparatus, comprising:
a calibration circuit configured to be coupled to a calibration impedance, the calibration circuit including:
a calibration driver circuit having an impedance that is adjustable and set by a calibration code and the calibration driver configured to be coupled to the calibration impedance;
a first code storage circuit configured to store a first calibration code that sets the calibration driver circuit to a first impedance;
a second code storage circuit configured to store a second calibration code that sets the calibration driver circuit to a second impedance; and
a multiplexer coupled to the first code storage circuit and the second code storage circuit, the multiplexer configured to provide the first calibration code or the second calibration code as an impedance code based on drive strength signals; and
a data output buffer circuit including a data driver circuit configured to provide an impedance that is set by the impedance code when activated to drive a logic level voltage on a data input/output terminal.

10. The apparatus of claim 9 wherein the calibration impedance comprises an adjustable calibration impedance.

11. The apparatus of claim 9 wherein the calibration impedance comprises an on-die calibration impedance.

12. The apparatus of claim 9 wherein the calibration impedance is on an external substrate and coupled to a terminal configured to be coupled to an external circuit.

13. The apparatus of claim 9 wherein the calibration impedance is included in a plurality of calibration impedances, and the calibration circuit is further configured to be coupled to the plurality of calibration impedances.

14. The apparatus of claim 13 wherein the calibration driver circuit is coupled to the plurality of calibration impedances and configured to be shared when determining respective calibration codes for each of the calibration impedances of the plurality.

15. The apparatus of claim 13 wherein the calibration driver circuit is included in a plurality of calibration driver circuits and each of the plurality of calibration driver circuits is configured to be coupled to a respective one of the plurality of calibration impedances.

16. The apparatus of claim 9 wherein the calibration driver circuit comprises a pulldown calibration driver circuit coupled to a reference voltage and configured to be coupled to the calibration impedance.

17. The apparatus to claim 9 wherein the data driver circuit of the output buffer circuit comprises a pullup data driver circuit included in a plurality of pullup data driver circuits of the output buffer circuit, and the output buffer circuit further includes a plurality of pulldown data driver circuits.

18. A method, comprising:
for a first calibration impedance, determining a first pulldown calibration code to set a replica pulldown driver circuit to a first impedance;
determining a first pullup calibration code for a replica pullup driver circuit based on the first impedance;
storing the first pulldown and pullup calibration codes;
for a second calibration impedance, determining a second pulldown calibration code to set the replica pulldown driver circuit to a second impedance;
determining a second pullup calibration code for the replica pullup driver circuit based on the second impedance; and
storing the second pulldown and pullup calibration codes.

19. The method of claim 18 wherein determining the first pulldown calibration code comprises determining a multibit count value that sets an impedance of a calibration pulldown driver circuit to cause a calibration node voltage to be equal to a reference electric potential, the multibit count value used as the first pulldown calibration code.

20. The method of claim 19 wherein determining the second pulldown calibration code comprises determining a multibit count value that sets an impedance of a second calibration pulldown driver circuit to cause a second calibration node voltage to be equal to the reference electric potential, the multibit count value used as the second pulldown calibration code.

21. The method of claim 19 wherein determining the second pulldown calibration code comprises determining a multibit count value that sets the impedance of the calibration pulldown driver circuit to cause the calibration node voltage to be equal to the reference electric potential, the multibit count value used as the second pulldown calibration code.

22. The method of claim 19 wherein determining the first pullup calibration code comprises determining a second multibit count value that sets an impedance of the replica pullup driver circuit to cause a second calibration node voltage to be equal to the reference electric potential, the second multibit count value used as the first pullup calibration code.

23. The method of claim 18, further comprising providing the first pulldown and pullup calibration codes or providing the second pulldown and pullup codes as an impedance code based on drive strength signals, the impedance code setting impedances for pulldown and pullup data driver circuits.

24. The method of claim 18, further comprising:
setting an impedance of an adjustable calibration impedance to the first calibration impedance; and
setting the impedance of the adjustable calibration impedance to the second calibration impedance.

25. A method for calibrating a data driver impedance, comprising:
for a first calibration impedance, selecting a first calibration driver circuit to receive a calibration code;
determining a first calibration code by adjusting the calibration code to set a first impedance of the first calibration driver circuit to cause a first calibration node voltage to be equal to a reference electric potential;
for a second calibration impedance that is different than the first calibration impedance, selecting a second calibration driver circuit to receive the calibration code;
determining a second calibration code by adjusting the calibration code to set a second impedance of the second calibration driver circuit to cause a second calibration node voltage to be equal to the reference electric potential.

26. The method of claim 25, further comprising:
determining a first pullup calibration code by adjusting the calibration code to set a first pullup impedance of a replica pullup driver circuit to cause a pullup calibration node voltage to be equal to the reference potential;
storing the first pulldown and pullup calibration codes in a first calibration code storage circuit;
determining a second pullup calibration code by adjusting the calibration code to set a second pullup impedance of the replica pullup driver circuit to cause the pullup calibration node voltage to be equal to the reference potential; and
storing the second pulldown and pullup calibration codes in a second calibration code storage circuit.

27. The method of claim 26, further comprising setting impedances of pullup and pulldown data driver circuits using the first pulldown and pullup calibration codes or second pulldown and pullup calibration codes based on drive strength settings.

28. The method of claim 25 wherein the first calibration code corresponds to a first drive strength setting and wherein the second calibration code corresponds to a second drive strength setting.

29. The method of claim 25 wherein adjusting the calibration code comprises changing a multibit count value based on calibration node voltage relative to the reference electric potential.
